(19) United States
(12) Patent Application Publication
(10) Pub. No.: US 2010/0105156 A1
(43) Pub. Date: Apr. 29, 2010

(54) METHOD OF MANUFACTURING LIGHT-EMITTING DIODE PACKAGE

(76) Inventors: Po-Shen CHEN, Chung-Ho City (TW); Li-Jen Ho, Chung-Ho City (TW); Shih-Tai Chuang, Chung-Ho City (TW); Hong-Syun Chou, Chung-Ho City (TW)

Correspondence Address: HDLS Patent & Trademark Services, P.O. BOX 220746, CHANTILLY, VA, 20153-0746, US

(21) Appl. No.: 12/258,576

(22) Filed: Oct. 27, 2008

(51) Int. Cl. H01L 33/00

(52) U.S. Cl. 438/27; 257/E33.061

(57) ABSTRACT

A method of manufacturing a light-emitting diode package, including following steps: providing a mounting base; providing a light-emitting chip on the mounting base, and the light-emitting chip including at least one electrode on the top surface thereof; forming a fluorescent layer on the top surface of the light-emitting chip, and the fluorescent layer covering the electrode; providing a laser generator to emit a focused laser beam to remove a portion of the fluorescent layer covered on the light-emitting chip to form a through-hole; providing a conductive wire to electrically connect the electrode of the light-emitting chip via the through-hole to the mounting base. The conductive wire can then be electrically connecting the electrode to the mounting base via the through-hole. Therefore, the thickness of fluorescent layer around the metal wire would be evenly formed, resulting better uniformity of white light mixing of the light-emitting diode package.

### BACKGROUND OF THE INVENTION

1. Field of the Invention

The present invention relates to a method of manufacturing a lighting device, in particular to a method of manufacturing a light-emitting diode package.

2. Description of Related Art

Light emitting diode (LED) has the advantages such as fast response rate, long life time and compact volume so as to be widely used as a light source of indicator or display. Since the development of white LED advances with increasing illuminating efficiency, the applications of LED in the general lighting field gradually get more attention.

Conventional white LED consists of a blue light-emitting chip and a fluorescent layer formed on top of the blue light-emitting chip. The fluorescent layer is capable of absorbing the blue light emitted from the blue light-emitting chip and emitting yellow light which can mix with the blue light to form white light. The fluorescent layer is formed by electrophoresis plating process or ink-jet printing process. Besides of the flip-chip type light-emitting chip, a conventional light-emitting chip needs to go through wire-bonding process, which a metallic conductive wire is formed and electrically connect from an electrode on the chip to a mounting base before the fluorescent layer can be formed on the light-emitting chip.

Since the fluorescent layer formed by electrophoresis plating process or ink-jet plating cannot easily form a through-hole using photo-lithography for wire-bonding process, the order of wire-bonding process and fluorescent forming process cannot be reversed. Furthermore, the abovementioned method using electrophoresis plating process or ink-jet plating will cause the thickness of the fluorescent layer around the metal wire to be uneven, which in turn, will affect the uniformity of white light mixing.

### SUMMARY OF THE INVENTION

The purpose of the present invention is to provide a method of manufacturing a light-emitting diode package, capable of providing a fluorescent layer of equal thickness on the light-emitting chip, in order to obtain better uniformity of the white light mixing.

In order to achieve aforementioned purpose, the present invention provides a method of manufacturing a light-emitting diode package, including following steps: (a) providing a mounting base; (b) providing a light-emitting chip on the mounting base, and the light-emitting chip including at least one electrode on the top surface thereof, (c) forming a fluorescent layer on the top surface of the light-emitting chip, and the fluorescent layer covering the electrode; (d) providing a laser generator to emit a focused laser beam to remove a portion of the fluorescent layer covered on the light-emitting chip to form a through-hole; (e) providing a conductive wire to electrically connect the electrode of the light-emitting chip via the though-hole to the mounting base.

The present invention utilizes focused laser beam to remove the portion of the fluorescent layer covered on the electrode of the light-emitting chip forming a through-hole which exposes the electrode. Then the conductive wire can electrically connect the electrode on the top surface of the light-emitting chip to the pad of the mounting base via the through-hole during wire-bonding process. Therefore, the thickness of fluorescent layer around the metal wire would be evenly formed, resulting better uniformity of white light mixing of the light-emitting diode package.

### BRIEF DESCRIPTION OF THE DRAWINGS

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 is a flow chart presenting a method of manufacturing a light-emitting diode package of the present invention;

FIGS. 2-7 are cross sectional views illustrating various stages during manufacturing the light-emitting diode package of the present invention.

### DETAILED DESCRIPTION OF THE INVENTION

A detailed description of the present invention will be made with reference to the accompanying drawings.

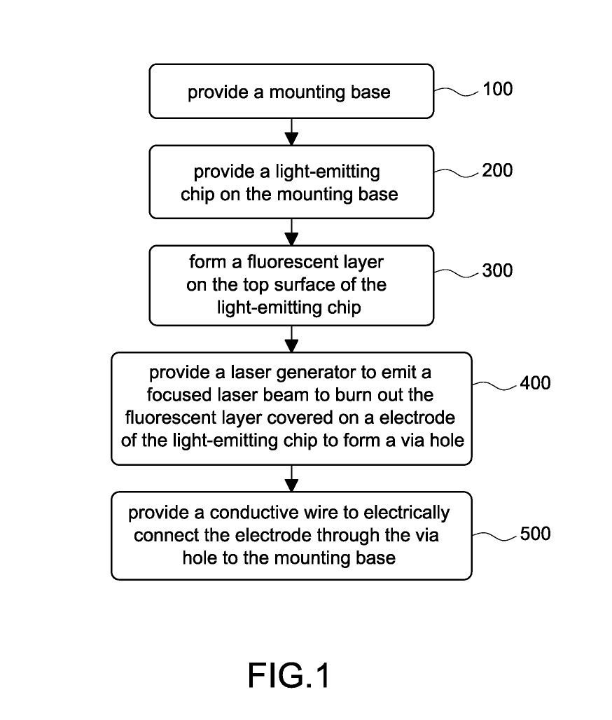

FIG. 1 shows a flow chart of a preferred embodiment of a method of manufacturing a light-emitting diode package of the present invention. The method includes the following steps:

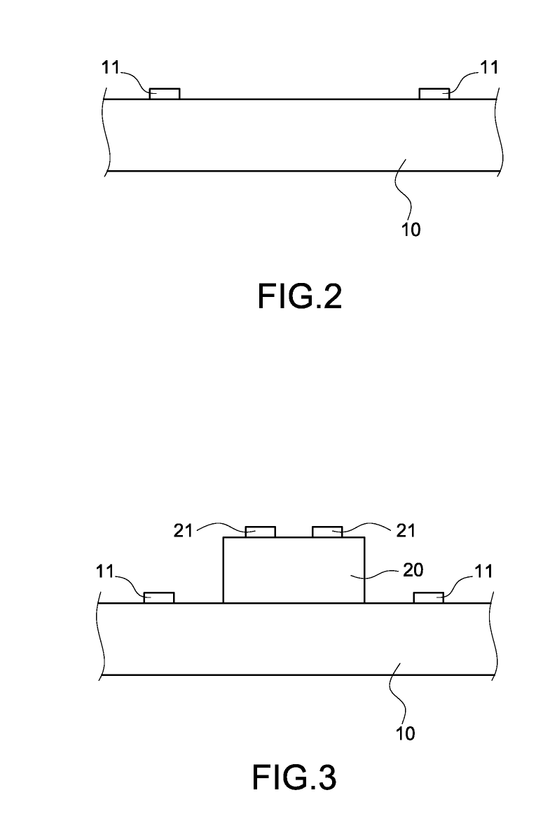

Firstly, in step 100, as FIG. 2 shows, a mounting base 10 having a flat top surface is provided. The mounting base 10 can be a lamp type mounting base or a surface mounted type mounting base and is not limited thereto and can be varied according to the actual condition. Two pads 11 are spaced on the top surface of the mounting base 10.

Then, in step 200, as FIG. 3 shows, a light-emitting chip 20 is arranged on the top surface of the mounting base 10. The light-emitting chip 20 includes two electrodes 21 made of metal material on the top surface thereof. In this embodiment, the light-emitting chip 20 is a light-emitting chip capable of emitting blue light and is not limited thereto in practical application.

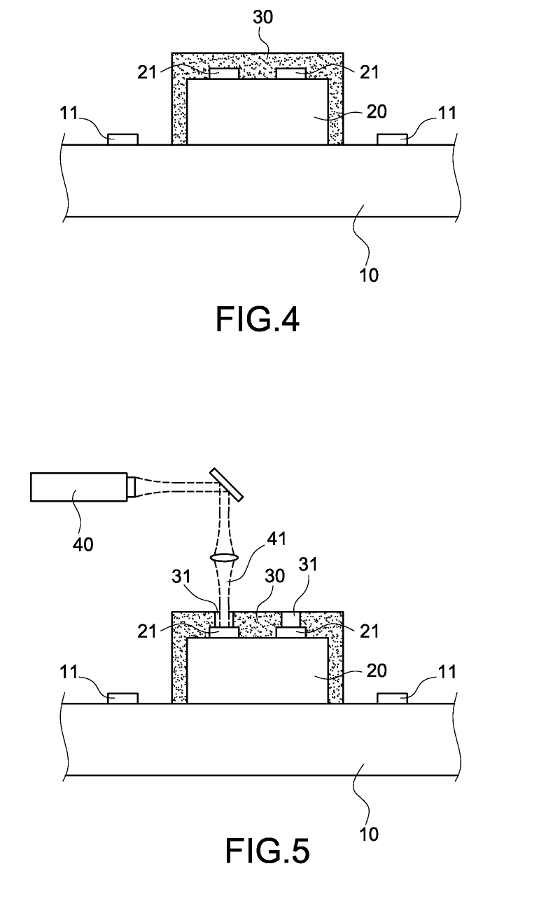

Next, in step 300, as FIG. 4 shows, a fluorescent layer 30 is formed on the light-emitting chip 20. The fluorescent layer 30 covers the top surface, the lateral surfaces and the electrodes 21 of the light-emitting chip 20. The fluorescent layer 30 includes fluorescent powder materials which can absorb a portion of light emitted from the light-emitting chip 20 and can transform the light into another light of different color. In this embodiment, the fluorescent layer 30 is formed by electrophoresis plating process or ink-jet printing process which attaches the fluorescent powder onto the light-emitting chip 20. The fluorescent powder can transform at least a portion of blue light emitted from the light-emitting chip 20 into yellow light and mix the yellow light with the other portion of blue light that is not absorbed by the fluorescent powder to form white light.

Then, in step 400, as FIG. 5 shows, a laser generator 40 is provided to emit a focused laser beam 41 to remove two portions of the fluorescent layer 30 covered on top of the electrodes 21 to form two through-holes 31 which expose at least a portion of the electrodes 21. The wavelength of the focused laser beam 41 is preferred to locate within the ultraviolet band so as to utilize the rather high energy photon of the ultraviolet laser beam to effectively burn through the material of the fluorescent layer 30. The laser generator 40 can be an excimer laser generator or a Nd: YAG laser generator.

Moreover, in step 400, in order to avoid damages to the electrodes 21 of the light-emitting chip 20 by the intensive focused laser beam 41 when the output power of the laser generator 40 is not under well control, a metal buffer layer can be further formed on the top surface of the electrodes 21 in advance to protect the electrodes 21. The metal buffer layer can be made of gold, aluminum, alloy of tin and gold, chromium or silver to provide better protecting effect.

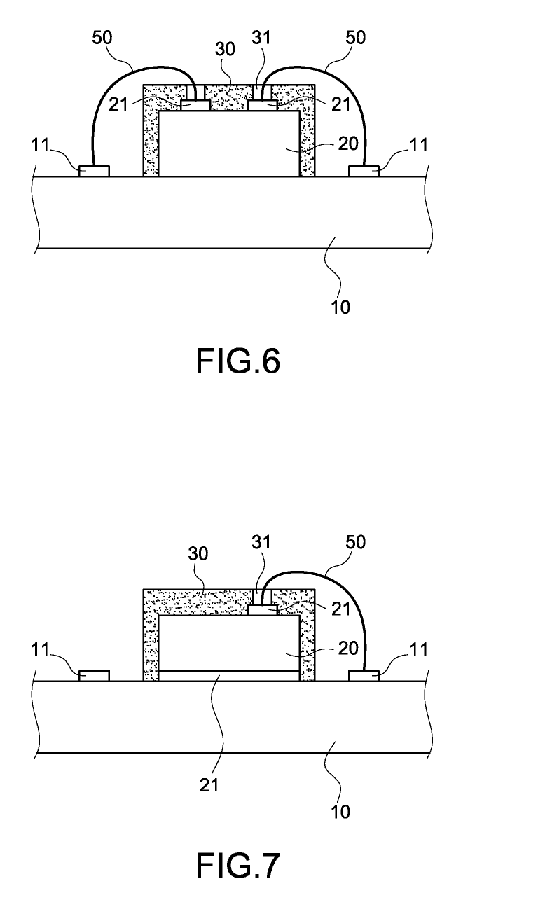

Finally, in step 500, as FIG. 6 shows, two conductive wires 50 are provided to electrically connect the electrodes 21 of the light-emitting chip 20 via the through-holes 31 to the pads 11 of the mounting base 10, respectively. Further, the conductive wires 50 are respectively bonded to the electrodes 21 and the pads 11 by wire-bonding process.

Besides, in this embodiment, the light-emitting chip 20 includes two electrodes 21 located on the top surface thereof. In practical application, as FIG. 7 shows, a light-emitting chip including two electrodes respectively located on the top surface and the bottom surface thereof is adopted as the light-emitting chip 20. The steps of manufacturing the light-emitting diode package in FIG. 7 are similar to the abovementioned steps 100 to step 500. The difference is that the electrode 21 on the bottom surface of the light-emitting chip 20 is in direct contacted with the mounting base 10 to form electrical connection. In this case, only one through-hole 31 needs to be formed on the fluorescent layer 30 on the top surface of light-emitting chip 20 by the focused laser beam for exposing at least a portion of the electrodes 21 on the top surface of the light-emitting chip 20. Hence, a conductive wire 50 can electrically connect the electrode 21 on the top surface of the light-emitting chip 20 to a pad 11 of the mounting base 10 via the through-hole 31.

Therefore, the present invention utilizes focused laser beam 41 to remove a portion of the fluorescent layer 30 covered on the electrodes 21 of the light-emitting chip 20 to form the through-holes 31 which expose the electrodes 21. The conductive wires 50 can electrically connect the electrodes 21 on the top surface of the light-emitting chip 20 to the pads 11 of the mounting base 10 via the through-holes 31. Therefore, the thickness of fluorescent layer 30 would be evenly formed throughout the emitting surfaces of light-emitting chip 20 obtaining uniform white light mixing of the light-emitting diode package.

Although the present invention has been described with reference to the foregoing preferred embodiment, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. A method of manufacturing a light-emitting diode package, comprising:
(a) providing a mounting base;
(b) providing a light-emitting chip on the mounting base, and the light-emitting chip comprising at least one electrode on the top surface thereof;
(c) forming a fluorescent layer on the top surface of the light-emitting chip, and the fluorescent layer covering the electrodes;
(d) providing a laser generator to emit a focused laser beam to remove a portions of the fluorescent layer covered on the light-emitting chip to form a through-hole;
(e) providing a conductive wire to electrically connect the electrode of the light-emitting chip via the through-hole to the mounting base.

2. The method according to claim 1, wherein the wavelength of the focused laser beam is located within the ultraviolet band.

3. The method according to claim 2, wherein the laser generator is an excimer laser generator.

4. The method according to claim 2, wherein the laser generator is a Nd: YAG laser generator.

5. The method according to claim 1, wherein the light-emitting chip is capable of emitting blue light and the fluorescent layer is able to transform a portion of blue light emitted from the light-emitting chip into yellow light.

6. The method according to claim 1, wherein the fluorescent layer is formed by electrophoresis plating process or ink-jet plating.

7. The method according to claim 1, wherein the electrodes is made of metal material.

8. The method according to claim 1, wherein a metal buffer layer is further formed on the top surface of the electrode.

9. The method according to claim 8, wherein the metal buffer layer is made of gold, aluminum, alloy of tin and gold, chromium or silver.

10. The method according to claim 1, wherein a pad for connecting with the conductive wire is arranged on the top surface of the mounting base.

11. The method according to claim 10, wherein the conductive wire is bonded to the electrode and the pad by wire-bonding process.
